(19) United States
(12) Patent Application Publication
(10) Pub. No.: US 2019/0353840 A1
(43) Pub. Date: Nov. 21, 2019

(54) DISPLAY MODULE AND BACKLIGHT MODULE

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Zheng WANG, Beijing (CN); Dake WANG, Beijing (CN); Xiuyun CHEN, Beijing (CN)

(73) Assignees: BOE Technology Group Co., Ltd., Beijing (CN); Beijing BOE Optoelectronics Technology Co., Ltd., Beijing (CN)

(21) Appl. No.: 15/781,661

(22) PCT Filed: Sep. 25, 2017
(86) PCT No.: PCT/CN2017/103160

§ 371 Date: Jun. 5, 2018

(30) Foreign Application Priority Data
Mar. 14, 2017 (CN) 201720245361.1

(51) Int. Cl. F21V 8/00; H05K 7/20

(52) U.S. Cl. CPC G02B 6/0085; H05K 7/2099

(57) ABSTRACT

The present disclosure provides a display module and a backlight module. The display module includes a back plate, a light source disposed on the inner side of the back plate, and a heat pipe, wherein the back plate is provided with vertically bent walls bent inwards around thereof, and wherein one side of a portion of the heat pipe is configured to abut against the light source, and the other side thereof is configured to abut against the vertically bent walls of the back plate.

### CROSS REFERENCE TO RELATED APPLICATIONS

This patent application is a National Stage Entry of PCT/CN2017/103160 filed on Sep. 25, 2017, which claims the benefit and priority of Chinese Patent Application No. 201720245361.1 filed on Mar. 14, 2017, the disclosures of which are incorporated herein by reference in their entirety as part of the present application.

### BACKGROUND

Embodiments of the present disclosure relate to the field of display technology, and in particular to a display module and a backlight module.

The temperature of an object is related to three factors: heat source, heat transfer, and heat dissipation. The heat source of a liquid crystal display module is mainly the LED (Light Emitting Diode) light strip. With the market's increasing demand for brightness of liquid crystal display modules, the current of the LED light strip is getting larger and larger, that is, the power of the heat source is getting larger and larger, which causes the temperature of the liquid crystal display module to be too high, and undesirable effects such as film wrinkling, LGP (light guide plate) warping, and poor LED lifetime, etc. are prone to occur, seriously affect the service life of the liquid crystal display module.

### BRIEF DESCRIPTION

A first aspect of the present disclosure provides a display module. The display module includes a back plate, a light source disposed on the inner side of the back plate, and a heat pipe, wherein the back plate is provided with vertically bent walls bent inwards around thereof, and wherein one side of a portion of the heat pipe is configured to abut against the light source, and the other side thereof is configured to abut against the vertically bent walls of the back plate.

According to some exemplary embodiments of the present disclosure, the sectional shape of the heat pipe is rectangular.

According to some exemplary embodiments of the present disclosure, the heat pipe is arranged in a rectangular shape on the inner side of the back plate and abuts against the vertically bent walls around the back plate.

According to other exemplary embodiments of the present disclosure, the heat pipe is arranged in a cross-in-rectangle shape on the inner side of the back plate, and the peripheral portions of the heat pipe abut against the vertically bent walls around the back plate.

According to further exemplary embodiments of the present disclosure, the heat pipe is arranged in a criss-cross pattern on the inner side of the back plate, and the peripheral portions of the heat pipe abut against the vertically bent walls around the back plate.

According to some exemplary embodiments of the present disclosure, the heat pipe is a single heat pipe.

According to some exemplary embodiments of the present disclosure, the heat pipe is formed by joining together a plurality of heat pipes.

A second aspect of the present disclosure provides a backlight module. The backlight module includes a back plate, a light source disposed on the inner side the back plate, and a heat pipe, wherein the back plate is provided with vertically bent walls bent inwards around thereof, and wherein, one side of a portion of the heat pipe is configured to abut against the light source, and the other side thereof is configured to abut against the vertically bent walls of the back plate.

### BRIEF DESCRIPTION OF THE DRAWINGS

FIG. 1 shows a partial structural cross-sectional view of a display module according to an embodiment of the present disclosure;

FIG. 2 shows a schematic exploded perspective view of a display module according to an embodiment of the present disclosure;

FIG. 3 shows a schematic plan view of a heat pipe in a rectangle arrangement on the inside of a back plate;

FIG. 4 shows a schematic plan view of a heat pipe in a cross-in-rectangle arrangement on the inner side of a back plate;

FIG. 5 shows a schematic exploded perspective view of a heat pipe in a cross-in-rectangle arrangement on the inner side of a back plate; and

FIG. 6 shows a schematic plan view of the heat pipe in a criss-cross arrangement on the inner side of the back plate.

### DETAILED DESCRIPTION

To enable those skilled in the art to better understand the solution of the present disclosure, a display module and a backlight module provided by specific embodiments of the present disclosure will be further described in detail with reference to the accompanying drawings. It will be apparent that the described and illustrated embodiments and their various specific features are merely illustrative of the disclosure and do not limit the disclosure. Based on the exemplary description, all other embodiments and specific features thereof obtained by a person of ordinary skill in the art without creative efforts shall fall within the protection scope of the present disclosure.

Embodiments of the disclosure utilize heat pipe technology. A heat pipe is a hollow metal pipe (such as a copper pipe) with a capillary structure woven by a copper wire mesh disposed inside its cavity, which, after having been pumped into close to vacuum, is filled with a medium that easily changes between gas and liquid phases, such as water, ethanol, methanol, etc. The end of the medium near the heat source undergoes a phase change due to heat, from a liquid state to a gaseous state, absorbing a large amount of heat, and quickly moves to the end away from the heat source, and changes from the gaseous state to the liquid state, releasing a large amount of heat, thereby achieving rapid heat transferring out. Therefore, the heat pipe is also called a heat superconductor.

The main heat source of a liquid crystal display module is the LED light strip. In order to transfer a large amount of heat generated in the working process to the entire back plate, an embodiment of the disclosure closely contacts one side of the heat pipe with the LED light strip, and contacts the other side with the back plate to achieve the purpose of lowering the thermal resistance, thereby lowering the temperature of the entire display module.

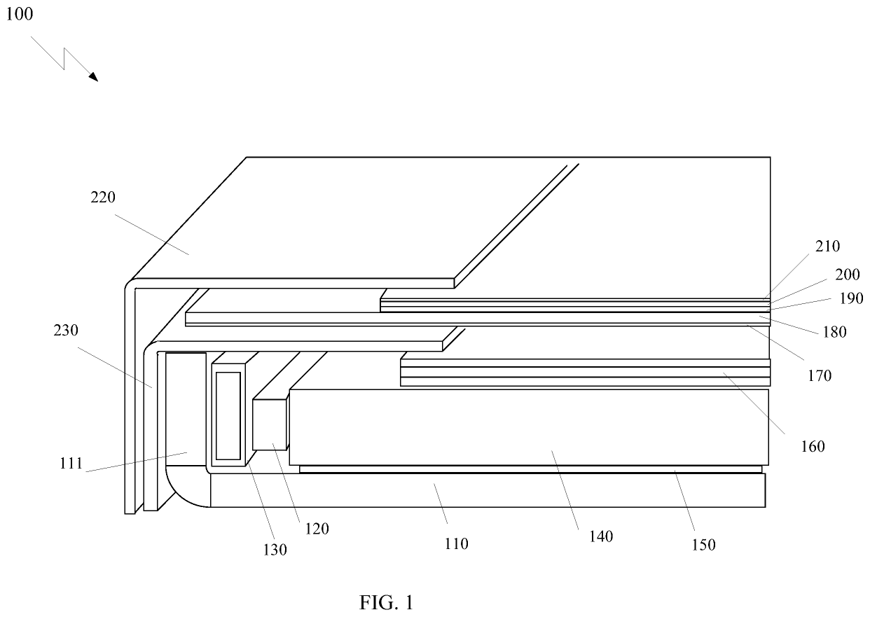

Referring now to FIG. 1, a partial structural cross-sectional view of a display module according to an embodiment of the present disclosure is shown.

As shown in FIG. 1, the display module 100 includes a back plate 110, a light source 120 disposed inside the back plate 110, and a heat pipe 130. Around the back plate 110 are vertically bent walls 111 bent inwards. One side of a portion of the heat pipe 130 abuts against the light source 120, and the other side abuts against the vertically bent walls 111 of the back plate 110.

The display module 100 is, for example, a liquid crystal display module. As known to those skilled in the art, the display module 100 may further include other components such as a light guide plate 140, a reflective sheet 150, a film (e.g., a diffuser) 160, a lower polarizer 170, a TFT (Thin Film Transistor) substrate 180, a liquid crystal layer 190, a CF (Color Film) substrate 200, an upper polarizer 210, a front frame 220, a support 230, and the like. These components may be the components of an existing liquid crystal display module, and therefore will not be described herein.

The back plate 110 is generally a rectangular flat plate, and around the back plate 110 are vertically bent walls 111 bent to the inside (i.e., the side facing the interior of the display module) so as to protect the internal components of the display module.

The light source 120 may be, for example, a light strip. The light strip may be, for example, an LED light strip. For example, the light source 120 may have an elongated shape, and its cross-sectional shape may be, for example, a rectangle. The light source 120 may be disposed near one edge of the inner side of the back plate 110, for example, and its light emitting surface may abut against a side of the light guide plate 140, so that the emitted light may be guided to the TFT substrate 180 and the CF substrate 200 through the light guide plate 140, the reflective sheet 150, etc.

According to some exemplary embodiments of the present disclosure, the sectional shape of the heat pipe 130 is rectangular. The configuration of the heat pipe 130 may include, for example, an outer copper pipe, a gas passage in the middle, and capillary channels at the periphery. One side of a portion (for example, the evaporation end) of the heat pipe 130 may abut against the light source 120 (for example, abut against the back surface of the light source 120), and the other side may abut against the vertically bent walls 111 of the back plate 110. The remaining portion of the heat pipe 130 may be distributed at other locations of the back plate in various ways so as to constitute the condensation end of the heat pipe 130.

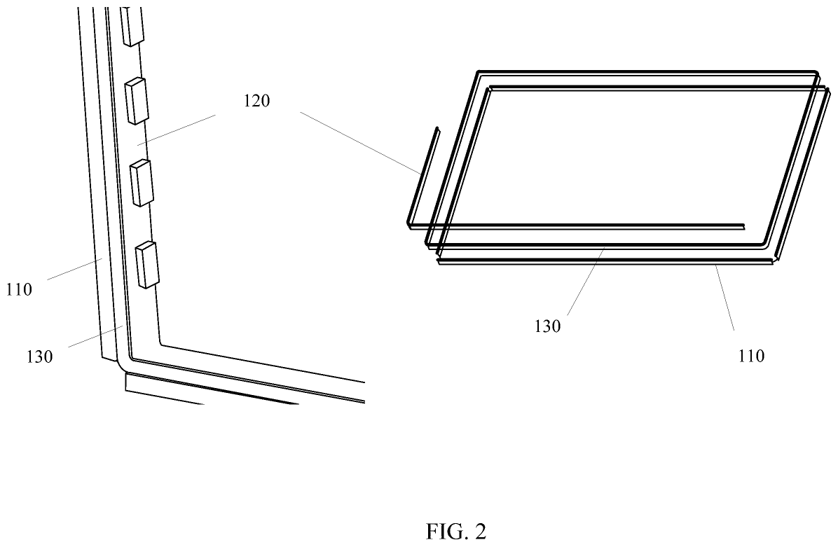

FIG. 2 shows a schematic exploded perspective view of a display module according to an embodiment of the present disclosure. As shown in FIG. 2, the light source 120 is mainly disposed along one edge of the inner side of the back plate 110, and is bent and disposed along a part of another edge of the inner side of the back plate 110. The heat pipe 130 is disposed at the periphery of the inner side of the back plate 110, and specifically abuts against the vertically bent walls (not shown in FIG. 2) around the back plate 110; a part (i.e., a portion capable of contacting with the light source 120) of the heat pipe 130 abuts against the light source 120, and can thus absorb heat from the light source 120 and transfer the heat to the remaining part of the heat pipe 130 for dissipation through the substrate.

The display module according to an embodiment of the present disclosure improves the heat transfer efficiency by using a heat pipe in contact with the light source, through one side of the heat pipe contacting the light source and the other side thereof contacting the vertically bent walls 111 of the back plate, the contact area is increased and the contact thermal resistance is reduced, thus facilitating the transferring out of heat, and the structure is simple and compact.

According to some exemplary embodiments of the present disclosure, the heat pipe 130 is arranged in a rectangular shape on the inner side of the back plate 110, and abuts against the vertically bent walls 111 around the back plate 110. Through the rectangular shape arrangement of the heat pipe 130 on the inner side of the back plate 110, the heat generated by the light source 120 can be conveniently transmitted to the periphery of the back plate, thereby facilitating heat dissipation.

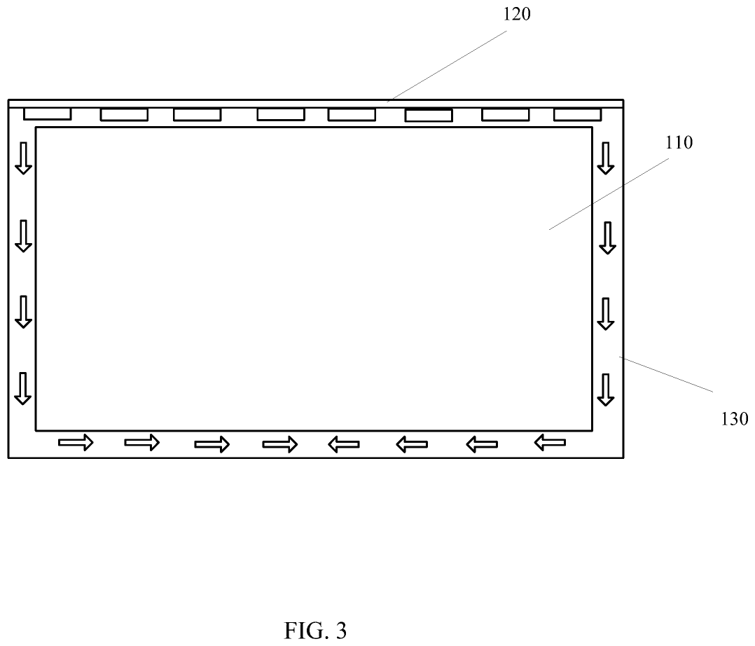

FIG. 3 shows a schematic plan view of the heat pipe in a rectangular shape on the inner side of the back plate, and the right half part of FIG. 2 shows a schematic exploded perspective view of the heat pipe in a rectangle arrangement on the inner side of the back plate. As shown in FIG. 3 and FIG. 2, the heat pipe 130 is arranged in a rectangular shape (i.e., rectangle) at the periphery of the inner side of the back plate 110, and abuts against the vertically bent walls 111 around the back plate 110. The heat pipe 130 may be, for example, a single heat pipe, so that the heat absorbed by the portion (evaporation end) of the heat pipe 130 in contact with the light source 120 is transmitted through the fluid in the heat pipe 130 to the remaining portion (the condensation end) of the heat pipe 130 located at the periphery of the back plate 110, and dissipated through the contacted vertically bent walls 111 around the back plate 110.

According to some other exemplary embodiments of the present disclosure, the heat pipe 130 is arranged in a cross-in-rectangle shape on the inner side of the back plate 110, and the peripheral portions of the heat pipes 130 abut against the vertically bent walls 111 around the back plate 110. Through the cross-in-rectangle shape arrangement of the heat pipe 130 on the inner side of the back plate 110, the heat generated by the light source 120 can be more evenly transferred to the periphery and the middle portion of the back plate, thereby facilitating heat dissipation and a more even temperature distribution on the entire back plate.

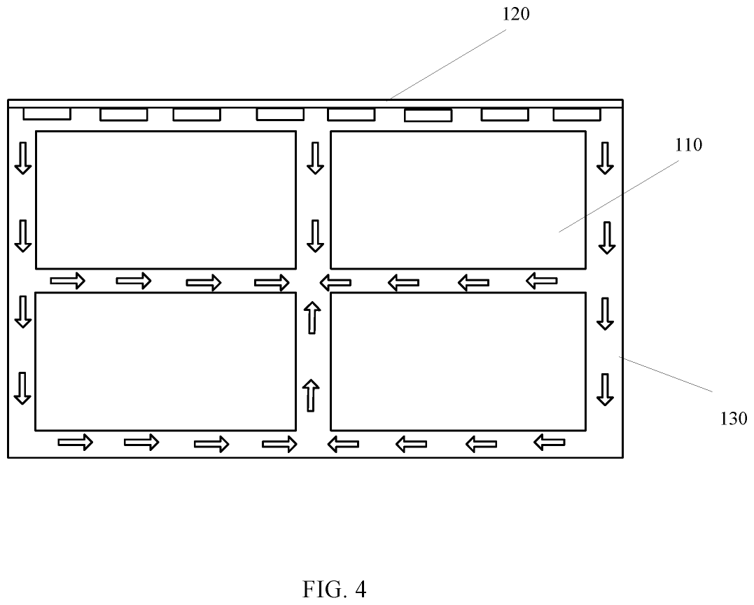

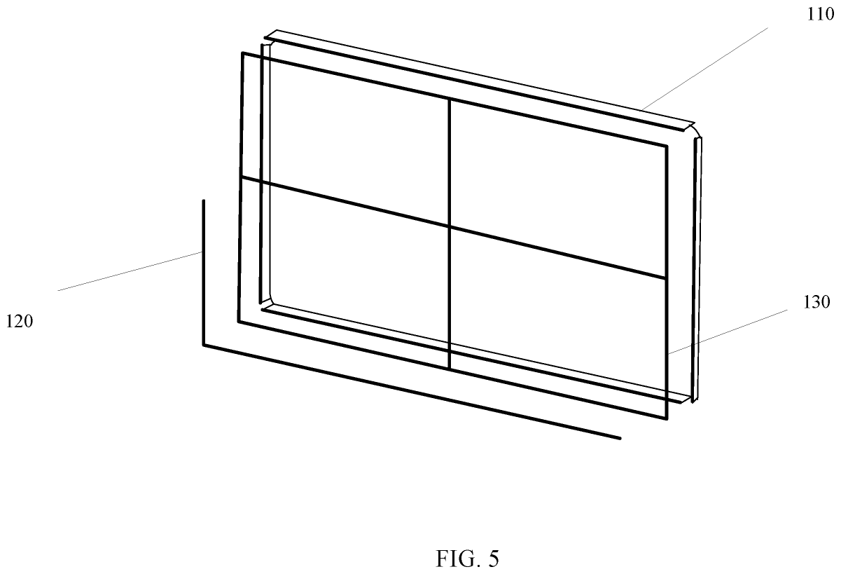

FIG. 4 shows a schematic plan view of the heat pipe in a cross-in-rectangle arrangement on the inner side of the back plate, and FIG. 5 shows a schematic exploded perspective view of the heat pipe in a cross-in-rectangle arrangement on the inner side of the back plate. As shown in FIG. 4 and FIG. 5, the heat pipe 130 is arranged in a cross-in-rectangle shape on the inner side of the back plate 110, and abut against the vertically bent walls 111 around the back plate 110.

The heat pipe 130 may be, for example, a single heat pipe, so that the heat absorbed by the portion (evaporation end) of the heat pipe 130 in contact with the light source 120 is transmitted through the fluid in the heat pipe 130 to the remaining part (condensation end) of the heat pipe 130 located at the periphery and middle portion of the back plate 110, and is dissipated through the vertically bent walls 111 around the contacted back plate 110 and the middle portion of the back plate.

Alternatively, the heat pipe 130 may be formed, for example, by joining together (for example, welding) a plurality of heat pipes. For example, the periphery of the cross-in-rectangle shape may be a heat pipe, and the middle cross of the cross-in-rectangle may be two heat pipes. The two heat pipes are joined together at the intersecting position and are joined together with the surrounding heat pipes. In this way, heat absorbed by the portion (evaporation end) of the heat pipe 130 in contact with the light source 120 is transmitted through the fluid in the same heat pipe 130 to the remaining portion (condensation end) of the heat pipe 130 located at the periphery of the back plate 110, and dissipated through the contacted vertically bent walls 111 around the back plate 110; at the same time, the heat absorbed by the portion (evaporation end) of the heat pipe 130 in contact with the light source 120 is also transmitted to the junctions with the other heat pipes through the fluid in the heat pipe, and the heat is transferred to the other heat pipes through heat conduction at the junctions, and through the fluid in the other heat pipes, further transferred to the rest of the other heat pipes and eventually dissipates through various portions of the back plate 110.

According to further exemplary embodiments of the present disclosure, the heat pipe is arranged in a criss-cross pattern on the inner side of the back plate, and the peripheral portions of the heat pipe abut against the vertically bent walls around the back plate. In other words, several horizontal heat pipes and several vertical heat pipes may be arranged on the inner side the heat pipe arranged in a rectangular shape at the periphery of the back plate. In addition, the heat pipes may also be arranged in any other shape on the inside of the back plate. For example, the heat pipes may be appropriately arranged according to factors such as the size and shape of the back plate, the heat dissipation requirements of the display module, and the temperature requirements of the components at various locations of the back plate, so as to better meet the heat dissipation requirements of the display module and achieve a favorable temperature distribution to prevent temperature-sensitive components from failing at high temperatures.

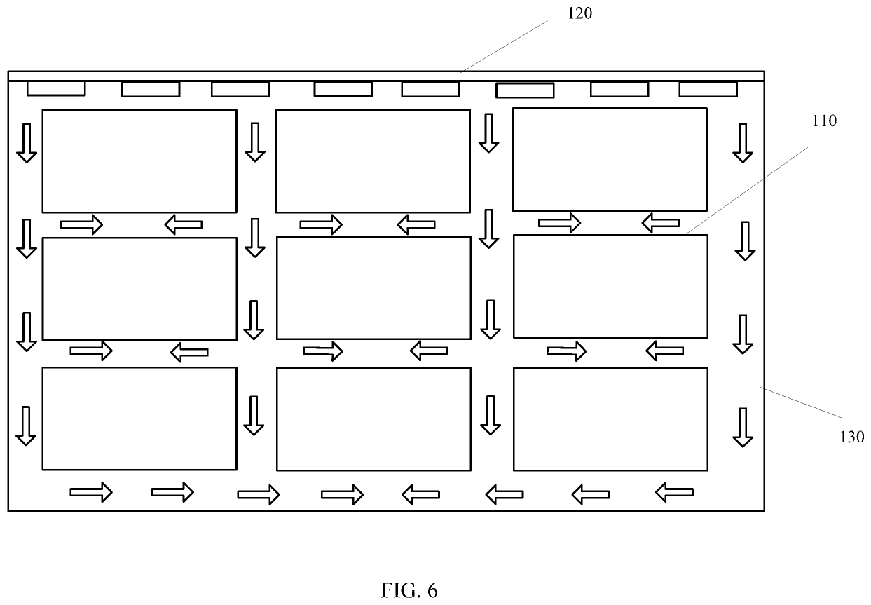

FIG. 6 shows a schematic plan view of the heat pipe in a criss-cross arrangement on the inner side of the back plate. As shown in FIG. 6, the heat pipe 130 is arranged in a criss-cross arrangement on the inner side of the back plate 110, and abuts against the vertically bent walls 111 around the back plate 110.

In an existing display module without a heat pipe, the heat generated by the light strip at the bottom is slowly transmitted along the back plate along a substantially horizontal gradient from the position of the light strip, thereby forming a substantially horizontal gradient temperature distribution on the back plate, and the maximum temperature at the light strip is high.

In a display module with a heat pipe arranged in a rectangular shape according to some embodiments of the present disclosure, the heat generated by the light strip at the bottom can be transmitted more quickly from the location of the light strip along the heat pipe to the periphery of the back plate and dissipated, thus forming a gradient temperature distribution with a middle depression on the back plate, and the maximum temperature at the light strip is lower than that of the existing display module.

In a display module with a heat pipe arranged in a cross-in-rectangle shape according to some other embodiments of the present disclosure, the heat generated by the light strip at the bottom can be more rapidly transmitted from the position of the light strip along the heat pipe to the periphery and middle part of the back plate to be dissipated, thus forming a curved gradient temperature distribution on the back plate, and the maximum temperature at the light strip and the temperatures at various locations of the back plate are further reduced compared to the above embodiment with a heat pipe in a rectangle arrangement.

As known to those skilled in the art, the combination of the back plate 110, the light source 120, the heat pipe 130, the light guide plate 140, the reflective sheet 150, the film (e.g., the diffuser) 160, etc. may also be referred to as a backlight module. Therefore, in another aspect, a backlight module is provided. The backlight module includes a back plate 110, a light source 120 disposed on the inner side of the back plate 110, and a heat pipe 130. Around the back plate 110 are vertically bent walls bent inwards, wherein one side of a portion of the heat pipe 130 abuts against the light source 120, and the other side thereof abuts against the vertically bent walls 111 of the back plate 110.

According to some exemplary embodiments of the present disclosure, the sectional shape of the heat pipe 130 is rectangular.

According to some exemplary embodiments of the present disclosure, the heat pipe 130 is arranged in a rectangular shape on the inner side of the back plate 110, and abuts against the vertically bent walls 111 around the back plate 110.

According to other exemplary embodiments of the present disclosure, the heat pipe 130 is arranged in a cross-in-rectangle shape on the inner side of the back plate 110, and the peripheral portions of the heat pipe 130 abut against the vertically bent walls 111 around the back plate 110.

According to further exemplary embodiments of the present disclosure, the heat pipe 130 is arranged in a criss-cross pattern on the inner side of the back plate 110, and the peripheral portions of the heat pipes 130 abut against the vertically bent walls 111 around the back plate 110.

According to some exemplary embodiments of the present disclosure, the heat pipe 130 is a single heat pipe.

According to some other exemplary embodiments of the present disclosure, the heat pipe 130 is formed by joining together a plurality of heat pipes.

The display module 100 and the backlight module according to embodiments of the present disclosure have been described above with reference to the accompanying drawings. It should be noted that the above illustration and description are only examples and do not limit the present disclosure. In embodiments of the disclosure, the display module 100 and the backlight module may have more, fewer, or different components, and the relationships of position, connection, and function of the various components may be different from those described and illustrated. For example, the display module 100 and the backlight module may further include other components. Since these components may be the same as those of an existing display module and backlight module, the description thereof is omitted herein.

It can be understood that the above embodiments of the present disclosure are merely exemplary embodiments employed for illustrating the principle of the present disclosure, and the present disclosure is not limited thereto. For a person of ordinary skill in the art, various variations and improvements may be made without departing from the spirit and essence of the present disclosure, and these variations and improvements are also considered to fall within the protection scope of the present disclosure. The scope of protection of the present disclosure is limited only by the meaning of the language of the appended claims and their equivalents.

1. A display module comprising a back plate, a light source disposed on an inner side of the back plate, and a heat pipe, wherein the back plate is provided with vertically bent walls bent inwards around the back plate, wherein one side of a portion of the heat pipe is configured to abut against the light source, and wherein the other side of the portion of the heat pipe is configured to abut against the vertically bent walls of the back plate.

2. The display module according to claim 1, wherein a cross-sectional shape of the heat pipe is rectangular.

3. The display module according to claim 1, wherein the heat pipe is arranged in a rectangular shape on the inner side of the back plate, and wherein the heat pipe abuts against the vertically bent walls around the back plate.

4. The display module according to claim 1, wherein the heat pipe is arranged in a cross-in-rectangle shape on the inner side of the back plate, and wherein peripheral portions of the heat pipe abut against the vertically bent walls around the back plate.

5. The display module according to claim 1, wherein the heat pipe is arranged in a criss-cross pattern on the inner side of the back plate, and wherein peripheral portions of the heat pipe abut against the vertically bent walls around the back plate.

6. The display module according to claim 1, wherein the heat pipe is a single heat pipe.

7. The display module according to claim 1, wherein the heat pipe is formed by joining together a plurality of heat pipes.

8. A display device, including the display module according to claim 1.

9. A display device, including the display module according to claim 2.

10. A display device, including the display module according to claim 3.

11. A display device, including the display module according to claim 4.

12. A display device, including the display module according to claim 5.

13. A display device, including the display module according to claim 6.

14. A display device, including the display module according to claim 7.
